(19) United States
(12) Patent Application Publication
(10) Pub. No.: US 2014/0108716 A1
(43) Pub. Date: Apr. 17, 2014

(54) DYNAMIC RANDOM ACCESS MEMORY FOR STORING RANDOMIZED DATA AND METHOD OF OPERATING THE SAME

(71) Applicant: SAMSUNG ELECTRONICS CO., LTD., SUWON-SI (KR)

(72) Inventors: SEUNG JUN BAE, HWASEONG-SI (KR); YOUNG SOO SOHN, SEOUL (KR); JIN SEOK KWAK, HWASEONG-SI (KR); JUNG BAE LEE, SEONGNAM-SI (KR)

(73) Assignee: SAMSUNG ELECTRONICS CO., LTD., SUWON-SI (KR)

(21) Appl. No.: 14/053,660

(22) Filed: Oct. 15, 2013

Related U.S. Application Data
(60) Provisional application No. 61/714,346, filed on Oct. 16, 2012.

(30) Foreign Application Priority Data
Mar. 15, 2013 (KR) 10-2013-0028272

(51) Int. Cl. G11C 11/406

(52) U.S. Cl. CPC G11C 11/40622
USPC 711/105

(57) ABSTRACT

A dynamic random access memory (DRAM) includes a memory cell array, a data input/output circuit, and a data randomizer configured to randomize data to be stored in the memory cell array. The data randomizer includes an encoder configured to generate write data by encoding input data received from the data input/output circuit using a randomization code and to output the write data to the memory cell array. The data randomizer further includes a decoder configured to generate output data by decoding read data received from the memory cell array using the randomization code and to output the output data to the data input/output circuit.

### CROSS-REFERENCE TO RELATED APPLICATIONS

A claim for priority under 35 U.S.C. §119(a) is made to U.S. Provisional Patent Application 61/714,346, filed on 16 Oct. 2012, in the U.S. Patent and Trademark Office, and Korean Patent Application No. 10-2013-0028272, filed on 15 Mar. 2013, in the Korean Intellectual Property Office, the entire contents of both of which are hereby incorporated by reference.

### BACKGROUND

Embodiments of the inventive concept relate to a dynamic random access memory (DRAM) and a method of operating the same.

DRAM stores data in a memory cell array including multiple memory cells. Each of the memory cells includes a transistor functioning as a switch and a capacitor connected in series to the transistor. A plate voltage is applied to the capacitors.

When each memory cell is activated or when data is written to the memory cell, noise may occur in the plate voltage due to a parasitic capacitor or the like. The noise increases when displacement of the proportion of “0” or “1” in data stored in the memory cells increases from 50 percent. The noise reduces the sensing margin of the memory cells.

### SUMMARY

According to embodiments of the inventive concept, there is provided a dynamic random access memory (DRAM) includes a memory cell array, a data input/output circuit, and a data randomizer configured to randomize data to be stored in the memory cell array. The data randomizer includes an encoder configured to generate write data by encoding input data received from the data input/output circuit using a randomization code and to output the write data to the memory cell array, and a decoder configured to generate output data by decoding read data received from the memory cell array using the randomization code and to output the output data to the data input/output circuit.

The data randomizer may further include a random number generator configured to generate and output the randomization code using at least part of an address corresponding to one of the input data and the read data. The address may be one of a column address and a row address, and the DRAM may receives the column address and the row address at different times according to a column address strobe signal and a row address strobe signal, respectively.

The encoder may perform a logical operation on the randomization code and the input data bit-to-bit to generate the write data and output the write data to the memory cell array. The decoder may perform a logical operation on the randomization code and the read data bit-to-bit to generate the output data and output the output data to the data input/output circuit.

The data input/output circuit may be configured to receive data having a burst length of at least 2 from each of multiple input/output ports of the DRAM, to parallelize the data from each input/output port, and to generate and output the input data.

The randomization code may include multiple sub-randomization codes corresponding to each of multiple input/output ports of the DRAM.

The sub-randomization codes may include a first sub-randomization code, and a second sub-randomization code having an inversion relationship with the first sub-randomization code. The first sub-randomization code corresponds to an odd-numbered input/output port among the multiple input/output ports and the second sub-randomization code corresponds to an even-numbered input/output port among the multiple input/output ports.

The random number generator may include at least one lookup table configured to store multiple pseudo-random binary sequences, and at least one selection circuit configured to select and output at least one pseudo-random binary sequence from a corresponding lookup table among the at least one lookup table according to bits in the address.

Each of the sub-randomization codes may include multiple bits in the address. Alternatively, each of the sub-randomization codes may be generated by performing a logical operation on multiple bits in the address and a pseudo-random binary sequence.

Alternatively, the random number generator may include at least one linear feedback shift register (LFSR) that uses multiple bits in the address as a reset signal.

According to other embodiments of the inventive concept, there is provided a method of operating a DRAM including a memory cell array and a data input/output circuit. The method includes encoding input data received from the data input/output circuit using a randomization code and outputting an encoding result to the memory cell array, and decoding read data received from the memory cell array using the randomization code and outputting a decoding result to the data input/output circuit.

The method of operating the DRAM may further include generating the randomization code using at least part of an address corresponding to one of the input data and the read data. The address may be one of a column address and a row address, and the DRAM may receive the column address and the row address at different times according to a column address strobe signal and a row address strobe signal, respectively.

The randomization code may include multiple sub-randomization codes corresponding to each of multiple input/output ports of the DRAM. The sub-randomization codes may be the same as each other. Alternatively, the sub-randomization codes may be different from each other.

According to other embodiments of the inventive concept, there is provided a data randomizer device configured to randomize write data received from a data input/output (I/O) circuit to be written in a memory cell array and read data received from the memory cell array. The data randomizer device includes a random number generator, an encoder and a decoder. The random number generator is configured to generate a randomization code using at least part of an address corresponding to input data from the data I/O circuit or read data from the memory cell array. The encoder is configured to encode the input data from the data I/O circuit using the randomization code from the random number generator, and to output write data to the memory cell array. The decoder is configured to decode the read data from the memory cell array using the randomization code from the random number generator, and to provide output data to the data input/output circuit.

The encoder may include multiple sub-encoders, a number of sub-encoders being equal to a number of bits in the input data. Also, the decoder may include multiple sub-decoders, a number of sub-decoders being equal to a number of bits in the read data. Each of the sub-encoders may perform one of an exclusive OR (XOR) operation or an exclusive NOR (XNOR) operation on a bit of the input data and a corresponding bit of the randomization code to generate a bit of the write data, and each of the sub-decoders may perform one of an XOR operation or an XNOR operation on a bit of the read data and a corresponding bit of the randomization code to generate a bit of the output data.

### BRIEF DESCRIPTION OF THE DRAWINGS

The above and other features and advantages of the inventive concept will become more apparent from the following description of exemplary embodiments with reference to the attached drawings, in which:

FIG. 1 is a block diagram of a dynamic random access memory (DRAM), according to embodiments of the inventive concept;

FIG. 2 is a block diagram of a data randomizer illustrated in FIG. 1, according to an embodiment of the inventive concept;

FIG. 3 is a circuit diagram of an encoder illustrated in FIG. 2, according to an embodiment of the inventive concept;

FIG. 4 is a diagram illustrating the operating principles of the encoder and a decoder illustrated in FIG. 2, according to an embodiment of the inventive concept;

FIG. 5 is a block diagram of an example of a random number generator illustrated in FIG. 2, according to an embodiment of the inventive concept;

FIG. 6 is a block diagram of a part of the random number generator illustrated in FIG. 5, according to an embodiment of the inventive concept;

FIG. 7 is a circuit diagram of an example of a selection circuit illustrated in FIG. 5, according to an embodiment of the inventive concept;

FIG. 8 is a table showing write data randomized using the random number generator illustrated in FIGS. 5 through 7, according to an embodiment of the inventive concept;

FIG. 9 is a schematic diagram of a memory cell array storing the randomized data illustrated in FIG. 8 and its periphery, according to an embodiment of the inventive concept;

FIG. 10 is a block diagram of another example of the random number generator illustrated in FIG. 2, according to an embodiment of the inventive concept;

FIG. 11 is a table showing write data randomized using the random number generator illustrated in FIG. 10, according to an embodiment of the inventive concept;

FIG. 12 is a block diagram of further another example of the random number generator illustrated in FIG. 2, according to an embodiment of the inventive concept;

FIG. 13 is a block diagram of the random number generator illustrated in FIG. 12, according to an embodiment of the inventive concept;

FIG. 14 is a block diagram of a linear feedback shift register illustrated in FIG. 13, according to an embodiment of the inventive concept;

FIG. 15 is a circuit diagram of yet another example of the random number generator illustrated in FIG. 2, according to an embodiment of the inventive concept;

FIG. 16 is a circuit diagram of still another example of the random number generator illustrated in FIG. 2, according to an embodiment of the inventive concept;

FIG. 17 is a flowchart of a method of operating a DRAM, according to embodiments of the inventive concept;

FIG. 18 is a block diagram of a computer system including the DRAM illustrated in FIG. 1, according to embodiments of the inventive concept;

FIG. 19 is a block diagram of a computer system including the DRAM illustrated in FIG. 1, according to other embodiments of the inventive concept;

FIG. 20 is a block diagram of a computer system including the DRAM illustrated in FIG. 1, according to other embodiments of the inventive concept; and

FIG. 21 is a block diagram of a computer system including the DRAM illustrated in FIG. 1, according to further embodiments of the inventive concept.

### DETAILED DESCRIPTION OF THE EMBODIMENTS

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc., may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. The term “exemplary” refers to an illustration or an example.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

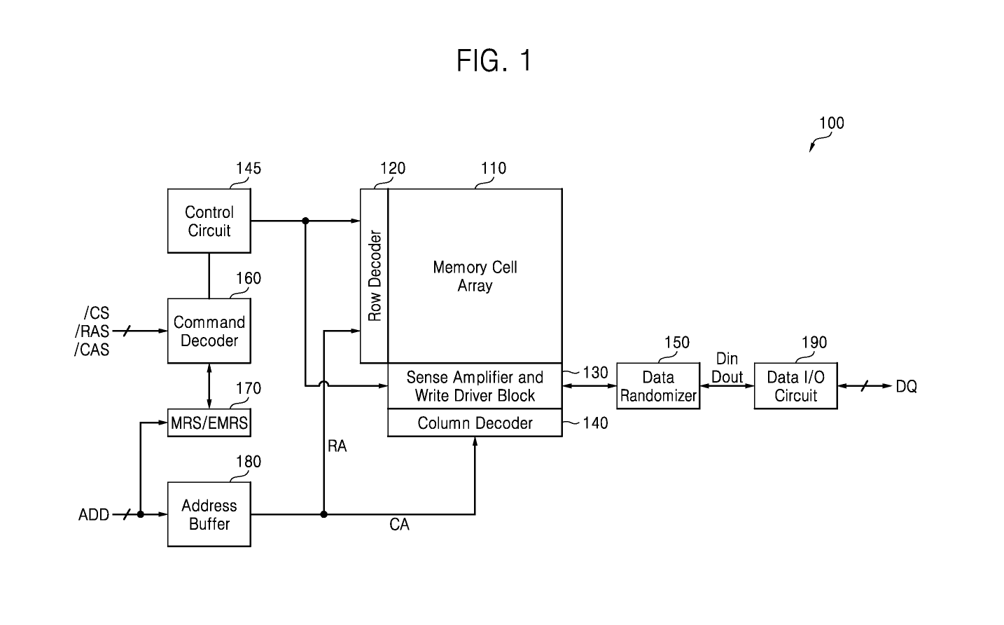

FIG. 1 is a block diagram of a dynamic random access memory (DRAM) 100, according to embodiments of the inventive concept. Referring to FIG. 1, the DRAM 100 includes a memory cell array 110, a row decoder 120, a sense amplifier and write driver block 130, a column decoder 140, a control circuit 145, a data randomizer 150, a command decoder 160, a mode register set/extended mode register set (MRS/EMRS) circuit 170, an address buffer 180, and a data input/output (I/O) circuit 190. Schematic operation of the DRAM 100 will be described below.

The memory cell array 110 includes a plurality of word lines or rows (not shown), a plurality of bit lines or columns (not shown), and a plurality of memory cells (not shown) storing data. The row decoder 120 decodes a row address RA output from the address buffer 180 and selects one of the rows or word lines according to the decoding result.

The sense amplifier and write driver block 130 may write data randomized by the data randomizer 150 to the memory cell array 110 based on an address signal ADD. The sense amplifier and write driver block 130 may also sense and amplify the randomized data from the memory cell array 110.

The column decoder 140 decodes a column address CA output from the address buffer 180 and selects columns according to the decoding result. The control circuit 145 controls operation of the DRAM 100 in response to commands output from the command decoder 160.

The data randomizer 150 encodes, i.e., randomizes data Din input through the data I/O circuit 190 and output randomized data to the memory cell array 110 through the sense amplifier and write driver block 130. Also, the data randomizer 150 decodes data read out from the memory cell array 110 and generates output data Dout.

The command decoder 160 receives external command signals, such as a chip select signal /CS, a row address strobe signal /RAS, and a column address strobe signal /CAS; decodes the external command signals; and internally generates decoded command signals. The MRS/EMRS circuit 170 sets an internal mode register (not shown) in response to an MRS/EMRS command for designating an operation mode of the DRAM 100 and the address signal ADD.

The address buffer 180 externally receives and temporarily stores the address signal ADD for designating a memory cell to which data will be written or from which data will be read. The address signal ADD includes information about the column address CA and information about the row address RA. The address buffer 180 receives the information about the column address CA and the information about the row address RA at different times according to the column address strobe signal /CAS and the row address strobe signal /RAS.

The data I/O circuit 190 receives the input data Din and outputs the output data Dout through multiple I/O ports DQ. The I/O ports DQ may receive external data having a burst length of at least 2, for example. The data I/O circuit 190 may parallelize the input data Din received through each of the I/O ports DQ when outputting it. For instance, the data I/O circuit 190 may include a parallelization buffer (not shown). The parallelization buffer may store bursts sequentially received through each of the I/O ports DQ, parallelize the bursts, and output them at the same time. In various embodiments, when the number of I/O ports DQ is “m” (where “m” is an integer of at least 2), a burst length is “n” (where “n” is an integer of at least 2), and the number of output bits of the data I/O circuit 190 is “x” (where “x” is an integer of at least 2), a relationship may be established that x=m*n.

However, the scope of the present teachings is not restricted to the above-described embodiments. Alternatively, the data randomizer 150 may perform data parallelization. As another alternative, the data I/O circuit 190 and the data randomizer 150 may perform data parallelization in conjunction with each other.

The data I/O circuit 190 may also serialize the output data Dout according to the number of I/O ports DQ. For instance, the data I/O circuit 190 may sequentially select and output “x” bits in the output data Dout to “m” I/O ports DQ.

Although not shown in FIG. 1, the DRAM 100 may also include a clock circuit that generates a clock signal and a power supply circuit that receives an external power supply voltage and generates an internal voltage or distributes the power supply voltage.

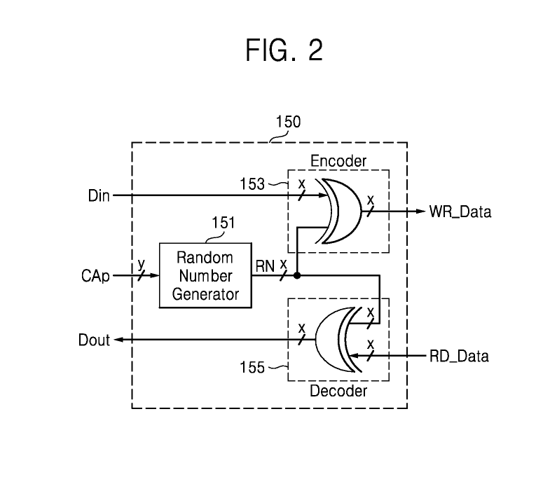

FIG. 2 is a detailed block diagram of the data randomizer 150 illustrated in FIG. 1, according to embodiments of the inventive concept. Referring to FIGS. 1 and 2, the data randomizer 150 includes a random number generator 151, an encoder 153, and a decoder 155.

The random number generator 151 generates and outputs a randomization code RN based on an address CAp corresponding to input data Din or read data RD_Data. The address CAp may be the column address CA or the row address RA and include multiple bits included in the column address CA or the row address RA. Hereinafter, it is assumed that the address CAp is composed of “y” bits (where “y” is an integer of at least 2) included in the column address CA and the randomization code RN is composed of “x” bits. The address CAp will be referred to as a sub-address CAp.

The encoder 153 receives the input data Din of “x” bits from the data I/O circuit 190. The data I/O circuit 190 may receive the input data Din having a burst length of “n” from “m” I/O ports DQ, parallelize the input data Din received from each of the I/O ports DQ, and generate and output the input data Din of “x” bits to the encoder 153. In various embodiments, it may be established that x=m*n. Hereinafter, it is assumed that x=m*n. However, the scope of the present teachings is not restricted to the current embodiments. When all of bursts in the input data Din are not parallelized by the data I/O circuit 190, the value of “x” may be changed.

The encoder 153 encodes the input data Din using the randomization code RN, generates write data WR_Data, and outputs the write data WR_Data to the memory cell array 110 through the sense amplifier and write driver block 130. The decoder 155 decodes the read data RD_Data of “x” bits received from the memory cell array 110, decodes the read data RD_Data using the randomization code RN, and generates and outputs the output data Dout to the data I/O circuit 190.

The randomization code RN, the input data Din, the output data Dout, the write data WR_Data, and the read data RD_Data are all x-bit data. Accordingly, the encoder 153 may perform a logical operation on the randomization code RN and the input data Din bit-to-bit, and the decoder 155 may perform a logical operation on the randomization code RN and the read data RD_Data bit-to-bit. The logical operation may be an exclusive OR (XOR) operation, for example, although the scope of the present teachings is not restricted thereto. For instance, the logical operation may be an exclusive NOR (XNOR) operation.

Hereinafter, the randomization code RN refers to all bits RN[1][1] through RN[m][n] included in the randomization code RN, for example. A reference character RN[m] indicates that the randomization code RN includes bits RN[m][1] through RN[m][n], and this rule applies to other data.

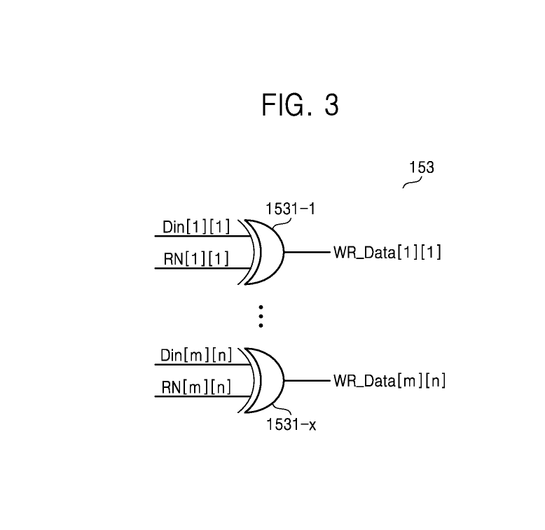

FIG. 3 is a detailed circuit diagram of the encoder 153 illustrated in FIG. 2, according to an embodiment of the inventive concept. Referring to FIGS. 1 and 3, the encoder 153 includes “x” sub-encoders 1531-1 through 1531-x. The input data Din is x-bit data and includes bits Din[1][1] through Din[m][n]. At this time, bit Din[m][n] is data of the n-th burst received from the m-th I/O port DQ of the DRAM 100.

The encoder 1531-x, for example, performs an XOR operation on a bit, e.g., Din[m][n] of the input data Din and a corresponding bit, e.g., RN[m][n] of the randomization code RN, to generate a bit WR_Data[m][n] of the write data WR_Data. The decoder 155 may be implemented in substantially the same manner as the encoder 153, except that read data RD_Data[m][n] and RN[m][n] would be input to generate Dout[m][n].

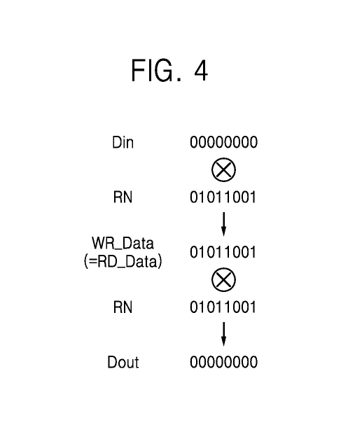

FIG. 4 is a diagram illustrating the operating principles of the encoder 153 and the decoder 155 illustrated in FIG. 2. When all bits of the input data Din are “0” is assumed to be one of the worst case scenarios in which noise occurs in a plate voltage. In this case, when the input data Din is written directly to the memory cell array 110, the sensing margin of memory cells decreases due to the noise in the plate voltage. Therefore, to reduce the noise (and to lessen or prevent decreasing the sensing margin), the input data Din needs to be randomized.

Referring to FIGS. 2 and 4, the encoder 153 performs an XOR operation on the input data Din and the randomization code RN, and generates the write data WR_Data. Each bit of the write data WR_Data has a value of “0” when a corresponding bit of the input data Din and a corresponding bit of the randomization code RN are the same as each other, and each bit has a value of “1” when a corresponding bit of the input data Din and a corresponding bit of the randomization code RN are different from each other. Since the input data Din and the randomization code RN are not functions of one another or otherwise related one another, the proportion of bits “0” or “1” in the resulting write data WR_Data is approximately 50 percent, meaning close enough to 50 percent to reduce the noise in the plate voltage, thus lessening or preventing decreases in the sensing margin. As a result, when the write data WR_Data is written to the memory cell array 110, the noise in the plate voltage is reduced.

When the write data WR_Data is subsequently read, that is, when the read data RD_Data is the same as the write data WR_Data, the sub-address CAp corresponding to the input data Din is the same as the sub-address CAp corresponding to the read data RD_Data, and the randomization code RN has the same value for reading and writing. The decoder 155 performs an XOR operation on the read data RD_Data and the randomization code RN and generates the output data Dout the same as the input data Din.

In the embodiments illustrated in FIG. 4, the same XOR operation is used for encoding and decoding. In other embodiments, the same XNOR operation may be performed for encoding and decoding. In further embodiments, different logical operations may be performed for encoding and decoding, respectively. Although encoding and decoding have been described when all bits of the input data Din are “0” in the embodiments illustrated in FIG. 4, this is just an example for the sake of convenience, and it is understood that the encoding and decoding according to the various embodiments may be performed on any bit pattern of the input data Din.

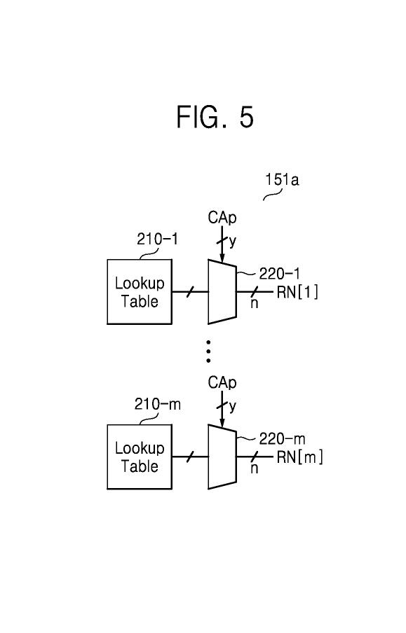

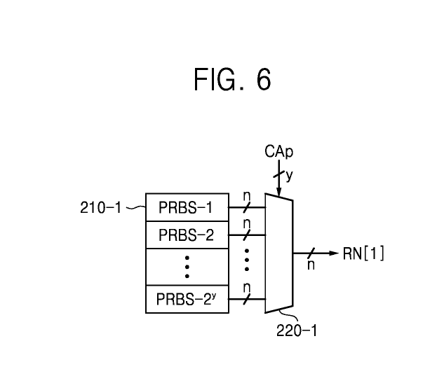

FIG. 5 is a block diagram of an example of the random number generator 151 illustrated in FIG. 2, according to an embodiment of the inventive concept. FIG. 6 is a detailed block diagram of a part of the random number generator 151a illustrated in FIG. 5, according to an embodiment of the inventive concept.

Referring to FIGS. 1, 2, and 5, the randomization code RN generated by the random number generator 151 includes multiple sub-randomization codes RN[1] through RN[m] respectively corresponding to multiple I/O ports DQ of the DRAM 100. Each of the sub-randomization codes RN[1] through RN[m] may include “n” bits. For instance, RN[m] may include bits RN[m][1] through RN[m][n]. The sub-randomization codes RN[1] through RN[m] may be generated using many different methods. Hereinafter, different embodiments of the random number generator 151 generating the sub-randomization codes RN[1] through RN[m] will be described with reference to FIGS. 5 through 16.

Referring to FIGS. 1, 5, and 6, the random number generator 151a includes multiple lookup tables 210-1 through 210-m and multiple selection circuits 220-1 through 220-m. The number of the lookup tables 210-1 through 210-m and the number of the selection circuits 220-1 through 220-m may be the same as the number “m” of the I/O ports DQ.

Each of the lookup tables 210-1 through 210-m may store multiple pseudo-random binary sequences (PRBSs). The number of PRBSs stored in each of the lookup tables 210-1 through 210-m may be 2^{y}. For instance, the first lookup table 210-1 may store PRBSs PRBS-1 through PRBS-2^{y}. Each PRBS may be an n-bit code. At this time, “y” is the number of bits included in the column address CA, i.e., the number of bits used by the random number generator 151a in the column address CA; and “n” is a burst length.

The selection circuits 220-1 through 220-m may receive PRBSs from the lookup tables 210-1 through 210-m, respectively, and may select and output one of the PRBSs as the n-bit sub-randomization codes RN[1] through RN[m], respectively, according to the sub-address CAp. For instance, the first selection circuit 220-1 may receive PRBSs PRBS-1 through PRBS-2^{y}, and select and output one of the PRBSs PRBS-1 through PRBS-2^{y} as the n-bit sub-randomization code RN[1] according to the y-bit sub-address CAp. Each of the selection circuits 220-1 through 220-m may be implemented using multiple multiplexers or switches.

The PRBSs stored in each the lookup tables 210-1 through 210-m may be the same as or different from each other. Accordingly, the sub-randomization codes RN[1] through RN[m] may be the same as or different from each other.

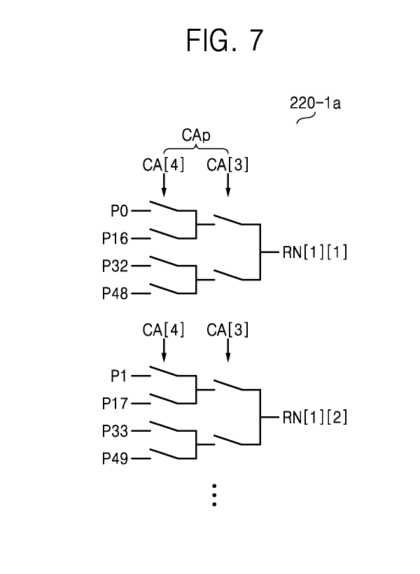

FIG. 7 is a circuit diagram of an example of the selection circuit 220-1 illustrated in FIG. 5. A selection circuit 220-1a generating the sub-randomization code RN[1] may include multiple switches. Hereinafter, for purposes of illustration, it is assumed that m=n=8, y=2, all bits of the input data Din are “0”, and the PRBSs stored in the lookup tables 210-1 through 210-m include bits P0 through P62 and 1.

Since y=2, the first lookup table 210-1 includes four PRBSs PRBS-1 through PRBS-4. It is assumed that the first PRBS PRBS-1 includes PRBS bits P0 through P7, the second PRBS PRBS-2 includes PRBS bits P16 through P23, the third PRBS PRBS-3 includes PRBS bits P32 through P39, and the fourth PRBS PRBS-4 includes PRBS bits P48 through P55. Thus, the four PRBSs PRBS-1 through PRBS-4 that the selection circuit 220-1a receives from the lookup table 210-1 include PRBS bits P0 through P7, P16 through P23, P32 through P39, and P48 through P55. Meanwhile, the selection circuit 220-1a receives the sub-address CAp, which includes a fourth bit CA4 and a third bit CA3 of the column address CA.

The selection circuit 220-1a outputs a PRBS bit included in one of the four PRBSs PRBS-1 through PRBS-4 as each of the bits RN[1][1] through RN[1][n]. For instance, when {CA4, CA3}={0, 0}, the selection circuit 220-1a outputs the PRBS bit P0 as the bit RN[1][1]; when {CA4, CA3}={0, 1}, the selection circuit 220-1a outputs the PRBS bit P16 as the bit RN[1][1]; when {CA4, CA3}={1, 0}, the selection circuit 220-1a outputs the PRBS bit P32 as the bit RN[1][1]; and when {CA4, CA3}={1, 1}, the selection circuit 220-1a outputs the PRBS bit P48 as the bit RN[1][1]. The other selection circuits 220-2 through 220-m may be implemented in the same manner as the selection circuit 220-1a and generate and output bits RN[2][1] through RN[m][n] using different PRBSs.

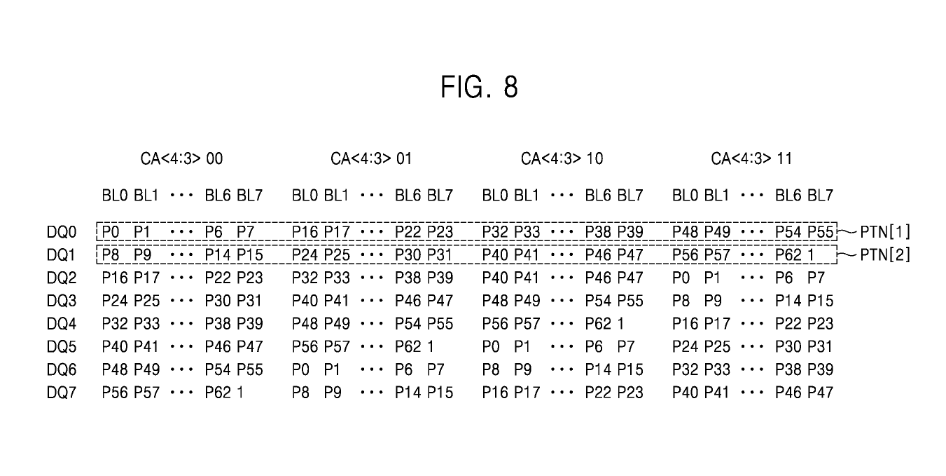

FIG. 8 is a table showing the write data WR_Data randomized using the random number generator 151a illustrated in FIGS. 5 through 7, according to an embodiment of the inventive concept. Referring to FIG. 1 and FIGS. 5 through 8, the table illustrated in FIG. 8 shows the randomization code RN depending on the values of the sub-address CAp. It is assumed that the I/O ports DQ include 8 I/O ports, i.e., first through eighth I/O ports DQ0 through DQ7, and that data received from each of the I/O ports DQ0 through DQ7 includes 8 bursts, i.e., first through eighth bursts BL0 through BL7.

When all bits of the input data Din are “0”, the write data WR_Data is the same as the randomization code RN. For instance, when {CA4, CA3}={0, 0}, RN[1][1] and WR_Data[1][1] corresponding to the first I/O port DQ0 and the first burst BL0 are P0. RN[1][8] and WR_Data[1][8] corresponding to the first I/O port DQ0 and the eighth burst BL7 are P7. RN[8][1] and WR_Data[8][1] corresponding to the eighth I/O port DQ7 and the first burst BL0 are P56. RN[8][8] and WR_Data[8][8] corresponding to the eighth I/O port DQ7 and the eighth burst BL7 are 1.

Each row in the table shows a PRBS pattern PTN. A PRBS pattern PTN[1] corresponding to the first I/O port DQ0 is {P0˜P7, P16˜P23, P32˜P39, P48˜P55}. The PRBS pattern PTN is determined by the PRBS of corresponding one of the lookup tables 210-1 through 210-m.

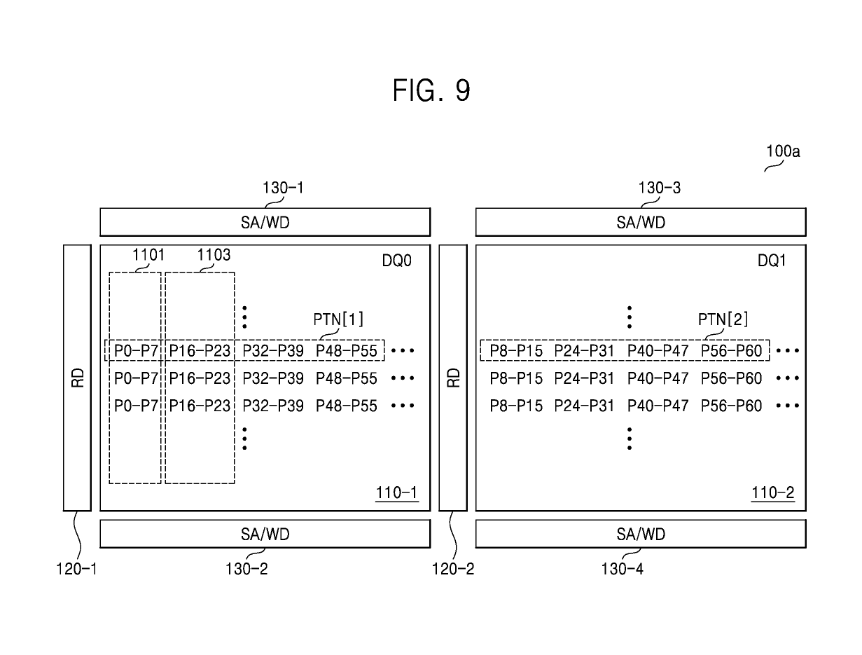

FIG. 9 is a schematic diagram of a memory cell array storing the randomized data illustrated in FIG. 8 and its periphery, according to an embodiment of the inventive concept. Referring to FIGS. 1, 8, and 9, DRAM 100a includes the memory cell array 110 including memory blocks 110-1 and 110-2 respectively corresponding to the I/O ports DQ0 and DQ1, row decoders 120-1 and 120-2, and sense amplifier and write driver blocks 130-1 and 130-2. The memory cell array 110 is divided into the memory blocks 110-1 and 110-2, and each of the memory blocks 110-1 and 110-2 corresponds to one I/O port DQ in the current embodiment, but the scope of the present teachings is not restricted thereto.

In writing data to the memory block 110-1 corresponding to the I/O port DQ0, the row decoder 120-1 may select one of word lines in the memory block 110-1. A column decoder (not shown) may select a group 1101 of first columns corresponding to {CA4, CA3}={0, 0}. The sense amplifier and write driver block 130-1 may write the PRBS bits P0 through P7 corresponding to DQ0 and {CA4, CA3}={0, 0} to the first columns, respectively, in the group 1101 in order of bursts.

The column decoder may select a group 1103 of first columns corresponding to {CA4, CA3}={0, 1}. The sense amplifier and write driver block 130-1 may write the PRBS bits P16 through P23 corresponding to DQ0 and {CA4, CA3}={0, 1} to the first columns, respectively, in the group 1103 in order of bursts. The procedure is repeated, so that a 32-bit PRBS pattern PTN appears in each row and is thus repeated in a column direction in each of the memory blocks 110-1 and 110-2.

It is important to randomize values in memory cells turned on when a word line is activated in order to reduce the noise in the plate voltage. When data is randomized using the column address CA, data of each column in a row can be randomized. The longer the PRBS pattern PTN, the more effectively the data can be randomized. The length of the PRBS pattern PTN can be increased by increasing the number of bits of the sub-address CAp.

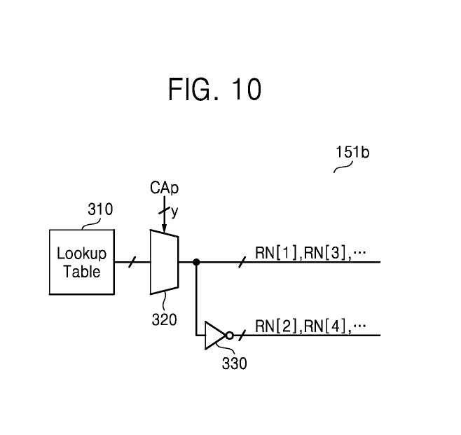

FIG. 10 is a block diagram of another example of the random number generator 151 illustrated in FIG. 2, according to an embodiment of the inventive concept. Referring to FIG. 10, the random number generator 151b includes a lookup table 310, a selection circuit 320, and an inverting circuit 330. The lookup table 310 stores multiple PRBSs. The selection circuit 320 may select “n” PRBSs from among the multiple PRBSs according to the sub-address CAp, and output an n-bit first sub-randomization code RN[1].

The inverting circuit 330 inverts the bits of the first sub-randomization code RN[1], and generates and outputs a second sub-randomization code RN[2]. The first sub-randomization code RN[1] may correspond to an odd-numbered I/O port DQ among the multiple I/O ports DQ and the second sub-randomization code RN[2] may correspond to an even-numbered I/O port DQ among the multiple I/O ports DQ. For instance, odd-numbered sub-randomization codes RN[1], RN[3], and RN[5] may be the same as one another. Meanwhile, the even-numbered sub-randomization codes RN[2], RN[4], and RN[6] may be the same as one another.

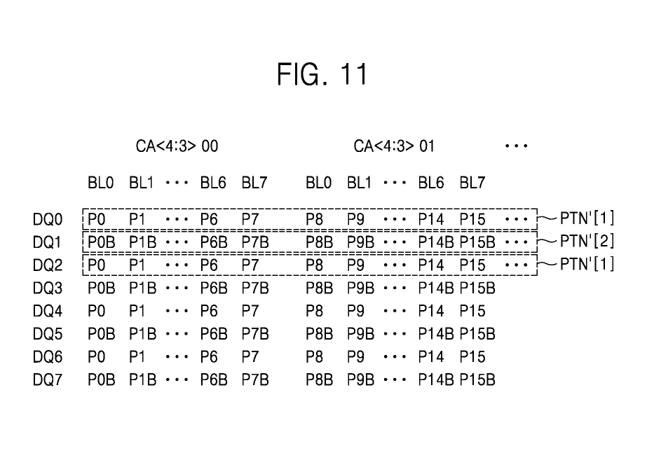

FIG. 11 is a table showing write data randomized using the random number generator 151b illustrated in FIG. 10, according to an embodiment of the inventive concept. A reference character “B” in a table entry indicates that the current bit is inverted. For instance, P0B denotes a bit obtained by inverting the bit P0. Referring to FIGS. 10 and 11, data “0000 . . . ” written to each word line in a memory block is changed to two PRBS patterns PTN′[1] (“P0, P1, P2, . . . ”) and PTN′2 (“P0B, P1B, P2B, . . . ”). Accordingly, the noise in the plate voltage is reduced by randomizing data in each column in a row.

The PRBS patterns PTN′[1] and PTN′2 in an odd-numbered memory block are the same as those in an even-numbered memory block when the structure shown in FIG. 10 is used. However, the noise in the plate voltage is lower than when the structure shown in FIG. 5 is used. Accordingly, noise can be more efficiently reduced using the simpler structure illustrated in FIG. 10 than the structure illustrated in FIG. 5.

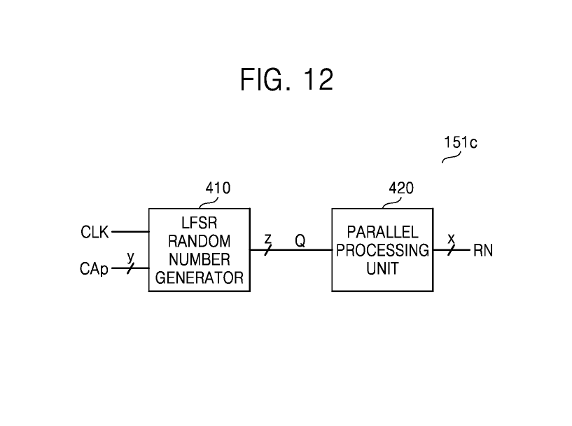

FIG. 12 is a circuit diagram of another example of the random number generator 151 illustrated in FIG. 2, according to an embodiment of the inventive concept. Referring to FIG. 12, a random number generator 151c includes a linear feedback shift register (LFSR) random number generator 410 and a parallel processing unit 420.

The LFSR random number generator 410 includes at least one LFSR. The LFSR random number generator 410 receives a clock signal CLK and the y-bit sub-address CAp, and generates and outputs a z-bit pseudo-random number Q. Here, “z” may be the product of “y” and the number of I/O ports, i.e., z=m*y. The parallel processing unit 420 converts the z-bit pseudo-random number Q into the x-bit randomization code RN.

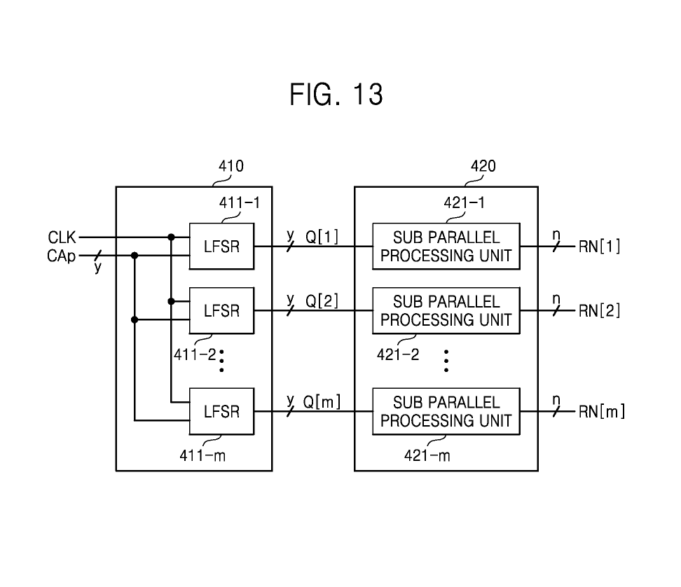

FIG. 13 is a block diagram of the random number generator 151c illustrated in FIG. 12, according to an embodiment of the inventive concept. Referring to FIG. 13, the LFSR random number generator 410 includes “m” LFSRs 411-1 through 411-m. The parallel processing unit 420 includes “m” sub-parallel processing units 421-1 through 421-m. The LFSRs 411-1 through 411-m and the sub-parallel processing units 421-1 through 421-m generate and use the sub-randomization codes RN[1] through RN[m], respectively.

The first LFSR 411-1 receives the clock signal CLK and the y-bit sub-address CAp, sets the sub-address CAp to a reset signal, i.e., an initial bit value (referred to as a seed), and generates a y-bit first pseudo-random number Q[1]. The first sub-parallel processing unit 421-1 parallelizes the y-bit first pseudo-random number Q[1], and generates and outputs the n-bit first randomization code RN[1]. The other LFSRs 411-2 through 411-m and the other sub-parallel processing units 421-2 through 421-m operate in substantially the same manner as the first LFSR 411-1 and the first sub-parallel processing unit 421-1.

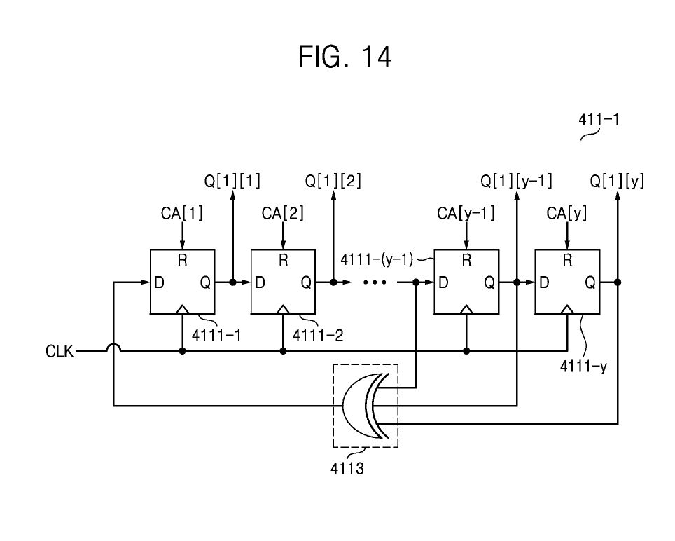

FIG. 14 is a circuit diagram of the first LFSR 411-1 illustrated in FIG. 13, according to an embodiment of the inventive concept. Referring to FIG. 14, the first LFSR 411-1 includes “y” D flip-flops 4111-1 through 4111-y and an operation circuit 4113. The first LFSR 411-1 generates the y-bit pseudo-random number Q[1] at each clock using the y-bit sub-address CAp as a seed. The structure and operation of an LFSR are apparent to those of ordinary skill in the art. Thus, detailed descriptions thereof will be omitted.

The LFSRs 411-1 through 411-m may have different structures. For instance, the order in which pseudo-random numbers Q[1] through Q[m] are extracted from the respective D flip-flops 4111-1 through 4111-y may be different, or the function or feedback structure of the operation circuit 4113 may be different. Accordingly, values of the pseudo-random numbers Q[1] through Q[m] and values of the sub-randomization codes RN[1] through RN[m] may be different.

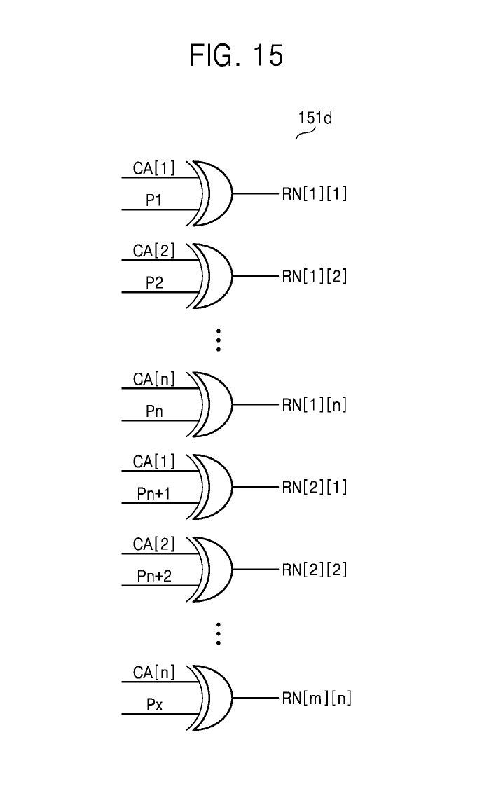

FIG. 15 is a circuit diagram of yet another example of the random number generator 151 illustrated in FIG. 2, according to an embodiment of the inventive concept. Referring to FIGS. 2 and 15, a random number generator 151d receives the n-bit sub-address CAp, performs a logical operation on “n” bits CA[1] through CA[n] of the sub-address CAp and PRBS bits P1 through Px, and generates the randomization code RN. Each of the sub-randomization codes RN[1] through RN[m] is obtained by performing the logical operation on the bits CA[1] through CA[n] and corresponding PRBS bits (e.g., P1 through Pn for the sub-randomization code RN[1]), respectively. The PRBS bits corresponding to each of the sub-randomization codes RN[1] through RN[m] may be the same as those corresponding to any other sub-randomization code among the sub-randomization codes RN[1] through RN[m] to simplify a circuit structure, or may be different from those corresponding to the other sub-randomization codes to further randomize data.

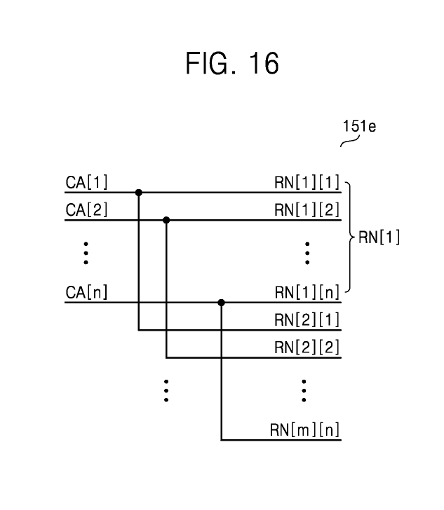

FIG. 16 is a circuit diagram of still another example of the random number generator 151 illustrated in FIG. 2, according to an embodiment of the inventive concept. Referring to FIGS. 2 and 16, a random number generator 151e receives the n-bit sub-address CAp and outputs the bits CA[1] through CA[n] of the sub-address CAp as each of the sub-randomization codes RN[1] through RN[m].

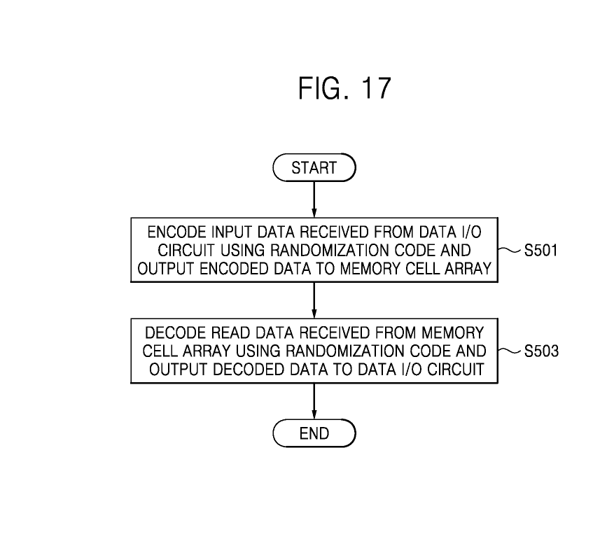

FIG. 17 is a flowchart of a method of operating the DRAM 100, according to embodiments of the inventive concept. Referring to FIGS. 1 and 17, in a write operation, the data randomizer 150 encodes the input data Din received from the data I/O circuit 190 using a randomization code, and outputs encoded data to the memory cell array 110 in operation S501. In a read operation, the data randomizer 150 decodes read data received from the memory cell array 110 using a randomization code, and outputs decoded data to the data I/O circuit 190 in operation S503.

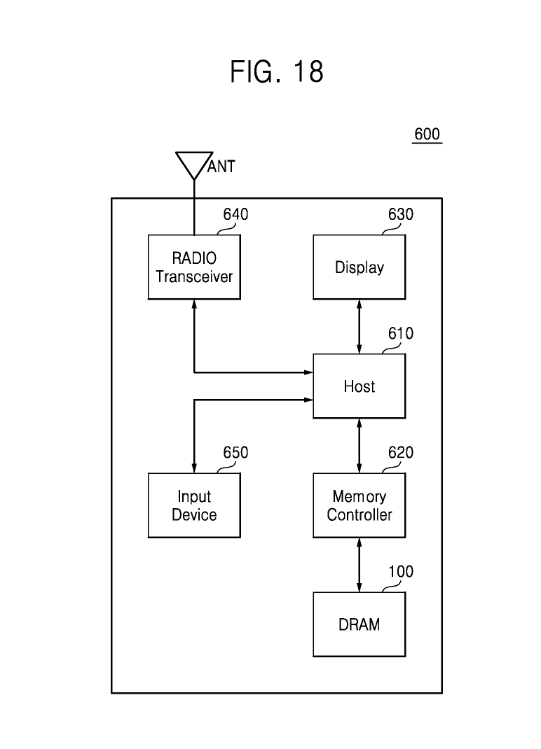

FIG. 18 is a block diagram of a computer system 600 including the DRAM 100 illustrated in FIG. 1, according to embodiments of the inventive concept. Referring to FIG. 18, the computer system 600 may be implemented as a cellular phone, a smart phone, a tablet personal computer (PC), a personal digital assistant (PDA) or a radio communication system, for example.

The computer system 600 includes the DRAM 100 and a memory controller 620 for controlling operations of the DRAM 100. The memory controller 620 may control the data access operations, e.g., write operations and read operations, of the DRAM 100 under control of a host 610. The data in the DRAM 100 may be displayed through a display 630 under control of the host 610 and the memory controller 620.

A radio transceiver 640 may transmit and receive radio signals through an antenna ANT. The radio transceiver 640 may convert radio signals received through the antenna ANT into signals that can be processed by the host 610. Accordingly, the host 610 may process the signals output from the radio transceiver 640 and transmit the processed signals to the memory controller 620 or the display 630. The memory controller 620 may store the signals processed by the host 610 to the DRAM 100. The radio transceiver 640 may also convert signals output from the host 610 into radio signals and outputs the radio signals to an external device through the antenna ANT.

An input device 650 enables control signals for controlling the operation of the host 610 and/or data to be processed by the host 610 to be input to the computer system 600. The input device 650 may be implemented by a pointing device, such as a touch pad or a computer mouse, a keypad, or a keyboard, for example.

The host 610 may control the operation of the display 630 to display data output from the memory controller 620, data output from the radio transceiver 640, and/or data output from the input device 650. The memory controller 620, which controls the operations of the DRAM 100, may be implemented as a part of the host 610 or as a separate chip.

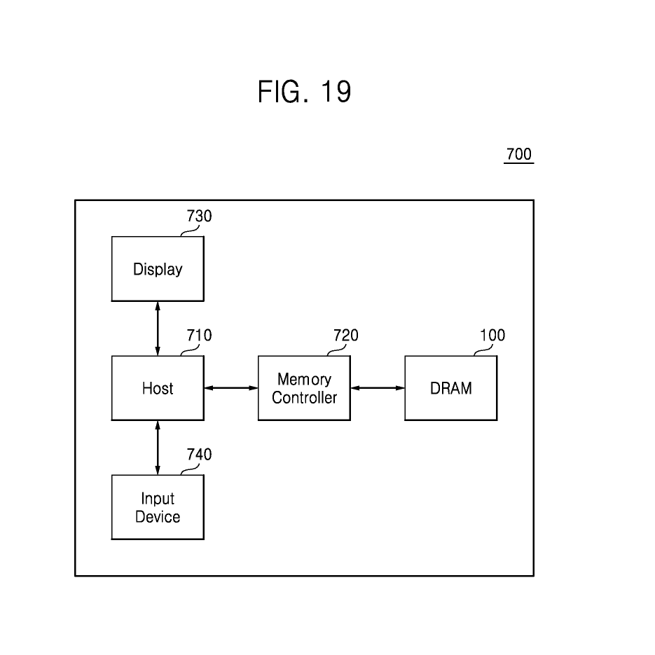

FIG. 19 is a block diagram of a computer system 700 including the DRAM 100 illustrated in FIG. 1, according to embodiments of the inventive concept. The computer system 700 may be implemented as a personal computer (PC), a tablet PC, a net-book device, an e-reader, a personal digital assistant (PDA), a portable multimedia player (PMP), an MP3 player, or an MP4 player, for example.

The computer system 700 includes a host 710, the DRAM 100, a memory controller 720 for controlling data processing operations of the DRAM 100, a display 730 and an input device 740. The host 710 may display data stored in the DRAM 100 through the display 730 according to data input through the input device 740. The input device 740 may be implemented by a pointing device, such as a touch pad or a computer mouse, a keypad, or a keyboard, for example.

The host 710 may control the overall operation of the computer system 700 and the operations of the memory controller 720. The memory controller 720, which may control the operations of the DRAM 100, may be implemented as a part of the host 710 or as a separate chip.

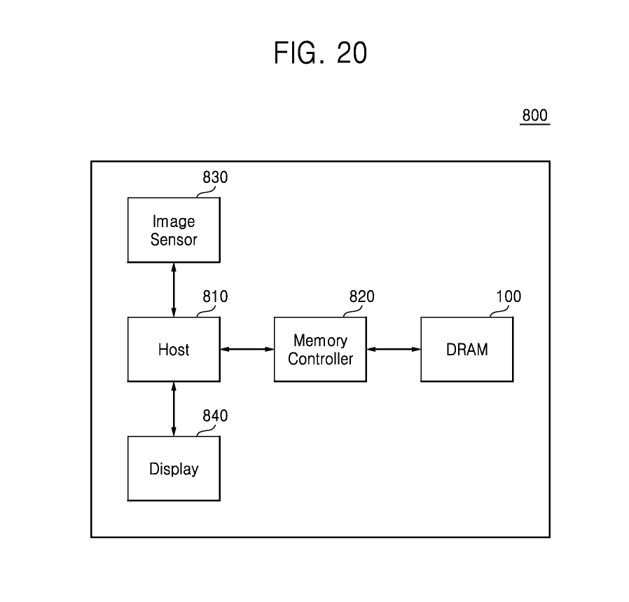

FIG. 20 is a block diagram of a computer system 800 including the DRAM 100 illustrated in FIG. 1, according to embodiments of the inventive concept. The computer system 800 may be implemented as an image processor, such as a digital camera, a cellular phone equipped with a digital camera, a smart phone equipped with a digital camera, or a tablet PC equipped with a digital camera, for example.

The computer system 800 includes the DRAM 100 and a memory controller 820 controlling the data processing operations, such as write operations and read operations, of the DRAM 100. The computer system 800 also includes an image sensor 830 and a display 840.

The image sensor 830 included in the computer system 800 converts optical images into digital signals, and outputs the digital signals to a host 810 and/or the memory controller 820. The digital signals may be controlled by the host 810 to be displayed through the display 840 and/or to be stored in the DRAM 100 through the memory controller 820.

Data stored in the DRAM 100 may be displayed through the display 840 under control of the host 810 and/or the memory controller 820. The memory controller 820, which may control the operations of the DRAM 100, may be implemented as a part of the host 810 or as a separate chip.

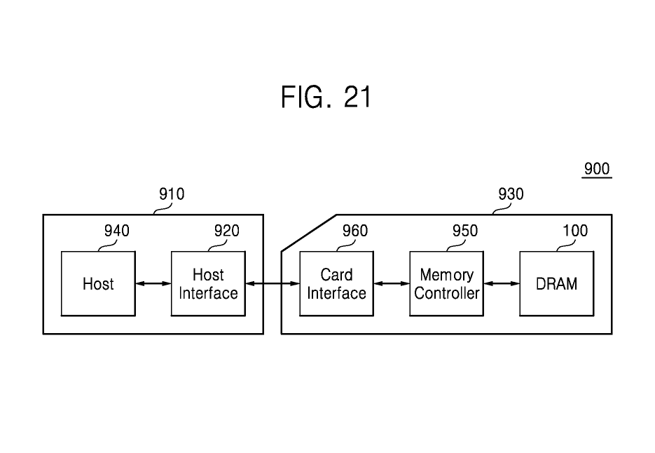

FIG. 21 is a block diagram of a computer system 900 including the DRAM 100 illustrated in FIG. 1, according to embodiments of the inventive concept. The computer system 900 is implemented as a host computer 910 and a smart card or memory card 930.

The computer system 900 includes the host computer 910 and the memory card 930. The host computer 910 includes a host 940 and a host interface 920. The memory card 930 includes the DRAM 100, a memory controller 950, and a card interface 960. The memory controller 950 may control data exchange between the DRAM 100 and the card interface 960. The card interface 960 may be a secure digital (SD) card interface or a multi-media card (MMC) interface, for example, although the scope of the present teachings is not restricted to these interfaces.

When the memory card 930 is connected with the host computer 910, the card interface 960 interfaces the host 940 via the host interface 920 and the memory controller 950 to enable data exchange according to the protocol of the host 940. For example, the card interface 960 may support a universal serial bus (USB) protocol and an interchip (IC)-USB protocol, although the scope of the present teachings is not restricted to these interfaces. Here, the card interface 960 may indicate hardware supporting a protocol used by the host computer 910, software installed in the hardware, and/or a signal transmission mode.

When the computer system 900 is connected with the host interface 920 of the host computer 910, such as a PC, a tablet PC, a digital camera, a digital audio player, a cellular phone, a console video game hardware, or a digital set-top box, the host interface 920 of the host 940 may perform data communication with the DRAM 100 through the card interface 960 and the memory controller 950 under control of the host 940.

As described above, according to embodiments of the inventive concept, data stored in memory cells are randomized, so that the proportion of bits “0” or “1” in the data is approximately 50 percent. As a result, the decrease in a sensing margin due to noise in a plate voltage is reduced.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A dynamic random access memory (DRAM), comprising:
a memory cell array;
a data input/output circuit; and
a data randomizer configured to randomize data to be stored in the memory cell array, the data randomizer comprising:
an encoder configured to generate write data by encoding input data received from the data input/output circuit using a randomization code and to output the write data to the memory cell array; and
a decoder configured to generate output data by decoding read data received from the memory cell array using the randomization code and to output the output data to the data input/output circuit.

2. The DRAM of claim 1, wherein the data randomizer further comprises:
a random number generator configured to generate and output the randomization code using at least part of an address corresponding to one of the input data and the read data.

3. The DRAM of claim 2, wherein the address is one of a column address and a row address, and the DRAM receives the column address and the row address at different times according to a column address strobe signal and a row address strobe signal, respectively.

4. The DRAM of claim 1, wherein the encoder performs a logical operation on the randomization code and the input data bit-to-bit to generate the write data and outputs the write data to the memory cell array, and the decoder performs a logical operation on the randomization code and the read data bit-to-bit to generate the output data and outputs the output data to the data input/output circuit.

5. The DRAM of claim 2, wherein the data input/output circuit is configured to receive data having a burst length of at least 2 from each of a plurality of input/output ports of the DRAM, to parallelize the data from each input/output port, and to generate and output the input data.

6. The DRAM of claim 2, wherein the randomization code comprises a plurality of sub-randomization codes corresponding to each of a plurality of input/output ports of the DRAM.

7. The DRAM of claim 6, wherein the sub-randomization codes comprise:
a first sub-randomization code; and
a second sub-randomization code having an inversion relationship with the first sub-randomization code,
wherein the first sub-randomization code corresponds to an odd-numbered input/output port among the plurality of input/output ports and the second sub-randomization code corresponds to an even-numbered input/output port among the plurality of input/output ports.

8. The DRAM of claim 6, wherein the random number generator comprises:
at least one lookup table configured to store a plurality of pseudo-random binary sequences; and
at least one selection circuit configured to select and output at least one pseudo-random binary sequence from a corresponding lookup table among the at least one lookup table according to a plurality of bits in the address.

9. The DRAM of claim 6, wherein each of the sub-randomization codes comprises a plurality of bits in the address.

10. The DRAM of claim 6, wherein each of the sub-randomization codes is generated by performing a logical operation on a plurality of bits in the address and a pseudo-random binary sequence.

11. The DRAM of claim 2, wherein the random number generator comprises at least one linear feedback shift register that uses a plurality of bits in the address as a reset signal.

12. The DRAM of claim 2, wherein the random number generator is configured to perform a plurality of logic operations on bits of the at least part of the address and bits of a pseudo-random binary sequence to generate the randomization code.

13. A method of operating a dynamic random access memory (DRAM) including a memory cell array and a data input/output circuit, the method comprising:
encoding input data received from the data input/output circuit using a randomization code and outputting an encoding result to the memory cell array; and
decoding read data received from the memory cell array using the randomization code and outputting a decoding result to the data input/output circuit.

14. The method of claim 13, further comprising:
generating the randomization code using at least part of an address corresponding to one of the input data and the read data.

15. The method of claim 14, wherein the address is one of a column address and a row address, and the DRAM receives the column address and the row address at different times according to a column address strobe signal and a row address strobe signal, respectively.

16. The method of claim 13, wherein the randomization code comprises a plurality of sub-randomization codes corresponding to each of a plurality of input/output ports of the DRAM, wherein the sub-randomization codes are the same as each other.

17. The method of claim 13, wherein the randomization code comprises a plurality of sub-randomization codes corresponding to each of a plurality of input/output ports of the DRAM, wherein the sub-randomization codes are different from each other.

18. A data randomizer device configured to randomize write data received from a data input/output (I/O) circuit to be written in a memory cell array and read data received from the memory cell array, the data randomizer device comprising:
a random number generator configured to generate a randomization code using at least part of an address corresponding to input data from the data I/O circuit or read data from the memory cell array;
an encoder configured to encode the input data from the data I/O circuit using the randomization code from the random number generator, and to output write data to the memory cell array; and
a decoder configured to decode the read data from the memory cell array using the randomization code from the random number generator, and to provide output data to the data input/output circuit.

19. The data randomizer device of claim 18, wherein the encoder comprises a plurality of sub-encoders, a number of sub-encoders being equal to a number of bits in the input data; and
wherein the decoder comprises a plurality of sub-decoders, a number of sub-decoders being equal to a number of bits in the read data.

20. The data randomizer device of claim 19, wherein each of the sub-encoders performs one of an exclusive OR (XOR) operation or an exclusive NOR (XNOR) operation on a bit of the input data and a corresponding bit of the randomization code to generate a bit of the write data, and
wherein each of the sub-decoders performs one of an XOR operation or an XNOR operation on a bit of the read data and a corresponding bit of the randomization code to generate a bit of the output data.
